(19) United States
(12) Patent Application Publication
(10) Pub. No.: US 2017/0063357 A1
(43) Pub. Date: Mar. 2, 2017

(54) METHOD, APPARATUS AND SYSTEM FOR USING TUNABLE TIMING CIRCUITS FOR FDSOI TECHNOLOGY

(71) Applicant: GLOBALFOUNDRIES Inc., Grand Cayman (KY)

(72) Inventors: Anurag Mittal, Malta, NY (US); Mahbub Rashed, Malta, NY (US)

(73) Assignee: GLOBALFOUNDRIES INC., GRAND CAYMAN (KY)

(21) Appl. No.: 14/838,215

(22) Filed: Aug. 27, 2015

(51) Int. Cl. H03K 5/14; H03K 19/0185; G06F 17/50

(52) U.S. Cl. CPC H03K 5/14; G06F 17/5045; G06F 17/5081; H03K 19/01855; H03K 2005/00019

(57) ABSTRACT

At least one method, apparatus and system disclosed involves providing a design for manufacturing a semiconductor device. An operation modeling of a semiconductor device circuit design is performed. At least one transistor is identified for providing at least one of a first voltage for forward biasing the transistor or a second voltage for reverse biasing the transistor. Selectively providing a delay for adjusting a timing associated with the transistor based upon identifying the at least one transistor for providing the at least one of a first voltage for forward biasing the transistor or a second voltage for reverse biasing.

### FIELD OF THE INVENTION

Generally, the present disclosure relates to the manufacture of sophisticated semiconductor devices, and, more specifically, to employing tunable timing circuits in FDSOI technology.

### DESCRIPTION OF THE RELATED ART

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a plurality of process technologies are currently practiced, wherein, for many types of complex circuitry, including field effect transistors, MOS technology is currently among the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. During fabrication of N-channel MOS (NMOS) devices and/or P-channel MOS (PMOS) devices, designers often control process steps to allow for increase current drive of those devices. For NMOS devices, the flow of electrons may be enhanced for increased current drive. For PMOS devices, the flow of “holes” may be enhanced for increased current drive. For example, a strained silicon layer is often formed to provide for improved transport of charge particles (i.e., electrons or holes).

There is a growing consensus in the industry that traditional methodology must be improved upon to provide smaller devices and devices that can operate at lower voltages. Currently, so-called bulk FETs are one of the more popular designs implemented in many devices. FIG. 1 illustrates a stylized depiction of a typical bulk FET 100 formed on a semiconductor wafer. The FET 100 is formed on a silicon substrate 105. An inversion layer 150 is formed on the silicon substrate 105. The inversion layer 150 is generally formed by depositing silicon oxide. A gate 100 is formed on the substrate 105, surrounded by insulation 120 formed during the processing of the wafer, which may be comprised of HfO₂.

A gate oxide layer 125 is formed over the inversion layer 150. The gate 120 of the FET 100 is formed over the gate oxide layer 125. FIG. 1 also illustrates the source region 140 and the drain region 130, which are formed at the top portion of the substrate 105. If the substrate 105 is of N-type, the drain and source regions 130, 140 would be of P-type, and vice versa. In this configuration, a depletion region 160 is created below the source region 140 and the drain region 130.

One of the problems associated with the typical bulk FET design of FIG. 1 includes the fact that these types of FETs can exhibit significant parasitic capacitance, leading to performance degradation and power loss. Further, due to the depletion region 160, current leakage may occur even when the FET 100 is off. Current leakage may include drain leakage current, source leakage current, and well leakage current. The FET 100 also tends to have a relatively high threshold voltage. Moreover, when supply voltage is reduced in order to decrease power consumption, the typical bulk FET design of FIG. 1 tends to exhibit performance degradation.

Designers have suggested utilizing the so-called silicon-on-insulator (SOI) design to address some of the deficiencies and problems exhibited by the typical bulk FET design of FIG. 1. SOI transistors are generally formed in thin layers of silicon that are isolated from the main substrate of a semiconductor wafer by using an electrical insulator, such silicon dioxide. The thin silicon layers may have thicknesses that range from several microns (typically for electrical power switching devices) down to less than 500 Å (typically for high-performance microprocessors). The isolation properties conferred by SOI designs provides for a reduction in the current leakage. SOI designs can provide other advantages such as faster operation of circuits and lower operating voltages. FIG. 2 illustrates a stylized depiction of a typical fully depleted (FD) SOI FET 200 formed on a semiconductor wafer.

The FD-SOI FET 200 is formed on a silicon substrate 205. The FET 200 comprises a depletion region 250 formed by depositing silicon oxide. A gate 200 is formed on the substrate 205, surrounded by insulation 220 formed during the processing of the wafer, and is generally comprised of HfO₂.

A gate oxide layer 225 is formed over substrate 205. The gate 220 of the FET 220 is formed over the gate oxide layer 225. The FET 200 also comprises a source region 240 and the drain region 240, which are formed at the top of the substrate 105. If the substrate 205 is of N-type, the drain and source regions 230, 240 would be of P-type, and vice versa. Further, the FET 200 comprises a buried oxide (BOX) region 270 below the drain and source regions 230, 240.

In this configuration, instead of a large depletion region 160 of FIG. 1, the depletion region 250 is confined above the BOX region 270 and between the drain and source regions 230, 240. The BOX region 270 is formed below the source region 140, the drain region 130 and the depletion region 250. The position of the BOX region 270 prevents the formation of a large depletion region similar to the depletion region 160 of FIG. 1. Further, the depletion region 250, in this case, is fully depleted. If the drain and source regions 230, 240 are of P-type, the depletion region 250 would be an N-type depleted region, and vice versa.

Further, FD-SOI FETs may be configured into a so-called LVT/SLVT format where a transistor pair comprises an NMOS FET formed over an N-well and a PMOS FET formed over a P-well, also referred to as flip-well configuration. Still further, FD-SOI FETs may be configured into a so-called RVT/HVT format, where a transistor pair comprises an NMOS FET formed over a P-well and a PMOS FET formed over an N-well. These configurations are described below.

One of the advantages of the FD SOI FET design is reduced threshold voltages, which allows for lower operating voltages. Other advantages include lower parasitic capacitance and lower leakage currents. However, one of the problems associated with the FD SOI FET design is that upon application of lower operating voltages, low V_{dd} timing violations may occur. In order to address timing errors, designers have resorted to providing targeted biasing voltages, i.e., forward biasing voltages for flip well (LSVT/LVT) configurations, and reverse biasing voltages for conventional well (RVT/HVT) configurations.

FIG. 3 illustrates a stylized depiction a typical transistor pair 400 formed in a LVT/SLVT configuration. FIG. 4 illustrates a stylized depiction of typical transistor pair 500 formed in an RVT/HVT configuration. Referring simultaneously to FIGS. 3 and 4, a transistor pair 300 (FIG. 4) comprises an NFET 301 and a PFET 302. FIG. 4 illustrates a transistor pair 400, which also comprises an NFET 401 and a PFET 402.

With regard to the transistor pair 300, the NFET 301 is formed on an N-well 375A, and comprises a gate 320A, a drain region 330A, and a source region 340A. The PFET 302 is formed on a P-well 375B, and comprises a gate 320B, a drain region 330B, and a source region 340B. The NFET 301 and PFET 302 are separated by a shallow trench isolation (STI) region 380.

The NFET 301 is formed over a BOX region 370A and the PFET 302 is formed over a BOX region 370B. The NFET 301 and PFET 302 respectively comprise fully depleted regions 350A and 350B. The fully depleted regions 350A, 350B are respectively located above the BOX regions 370A, 370B and between the source and drain regions of the FETs 301, 302.

With regard to the transistor pair 400, the NFET 401 is formed on a P-well 475A, and comprises a gate 420A, a drain region 430A, and a source region 440A. The PFET 402 is formed on a P-well 475B, and comprises a gate 420B, a drain region 430B, and a source region 440B. The NFET 401 and PFET 402 are separated by a shallow trench isolation (STI) region 480.

The NFET 401 is formed over a BOX region 470A and the PFET 440B is formed over a BOX region 470B. The NFET 402 and PFET 440B respectively comprise fully depleted regions 450A and 450B. The fully depleted regions 450A, 450B are located above the BOX regions 470A, 470B and between the source and drain regions of the FETs 401, 402.

As indicated in FIGS. 3 and 4, the LVT/SLVT FETs 301, 302 are capable of being forward biased, wherein the RVT/HVT FETs 401, 402 are capable of being reversed biased. In order to adjust for any timing issues resulting from operation of the FD SOI FETs (e.g., timing errors due to low Vdd), designers have introduced forward or reverse biasing schemes. However, state of the art forward/reverse biasing schemes require timing adjustments, such as insertion of delay buffers.

FIG. 5 illustrates a typical circuit that utilizes FD SOI FETs, and thus can operate at lower operating voltages. FIG. 5 illustrates a state of the art insertion of delay buffers in a FD SOI FET circuit. FIG. 5 shows a circuit 500 that comprises a 1^{st} logic block 510, a 2^{nd} logic block 520, a cone of logic 530, a set of delay cells 540, and insertions delay buffers 550. The 1^{st} and 2^{nd} logic blocks 510, 520 each may represent one or more registers and/or other logic.

The implementation of FD SOI FETs allows for lower operation voltages for the circuit 500, thus the V_{dd} minus V_{T} headroom is reduced. This may cause various problems, such as timing failures, skew in the p/n ratio, V_{T} skew, RC coupling problems. In order to address the timing problems in critical paths, delays are introduced into those critical paths. The path between the 1^{st} logic 520, the cone of logic 530 and the 2^{nd} logic block 520 may comprise critical path for SET-UP or HOLD paths.

In some cases, critical path delay may increase significantly when operating voltages are reduced, e.g., SET-UP and HOLD time errors may occur. The delay cells 540 may be added to implement desired timing adjustments for SET-UP and HOLD paths to reduce timing errors. Further, the insertion delay buffers 550 may be implemented to adjust for SET-UP and HOLD timing that may be caused by the variability at near-threshold operation of the FD SOI transistors, which may be operating at lower V_{dd}. However, the delay buffers 550 can be costly in terms or area and power consumption. Further, the delay buffers 550 are fixed and may not adequately address the timing problems of the circuit 500. Moreover, state of the art adjustments tend to increase critical path delays, which can negatively impact the frequency of maximum power gain of unity of the transistors (Fₘₐₓ).

Designers have implemented biasing voltages to the FD SOI FETs to adjust for critical path delays. However, producing the necessary voltage signals, e.g., using voltage dividers, regulators, etc., can be costly in terms of power consumption and area utilization on a semiconductor wafer. Further, routing the biasing voltages may be difficult in dense circuits. Further, the state of the art is directed to biasing entire blocks of FETs, which causes significant leakage currents, and reduces the power consumption benefits of using lower operating voltages.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to at least one method, apparatus and system disclosed involves providing a design for manufacturing a semiconductor device. An operation modeling of a semiconductor device circuit design is performed. At least one transistor is identified for providing at least one of a first voltage for forward biasing the transistor or a second voltage for reverse biasing the transistor. Selectively providing a delay for adjusting a timing associated with the transistor based upon identifying the at least one transistor for providing the at least one of a first voltage for forward biasing the transistor or a second voltage for reverse biasing.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a typical bulk FET formed on a semiconductor wafer;

FIG. 2 illustrates a stylized depiction of a typical fully depleted (FD) SOI FET formed on a semiconductor wafer;

FIG. 3 illustrates a stylized depiction a typical transistor pair 400 formed in a LVT/SLVT configuration;

FIG. 4 illustrates a stylized depiction of typical transistor pair 500 formed in an RVT/HVT configuration;

FIG. 5 illustrates a typical circuit that utilizes FD SOI FETs;

FIG. 6 illustrates a stylized depiction of an exemplary circuit having FD SOI devices, in accordance with embodiment herein;

FIG. 7 illustrates a stylized block diagram depiction of a bias voltage module and a clock tuning module, in accordance with embodiments herein;

FIG. 8 illustrates a PFET to generate a bias voltage, in accordance with embodiments herein;

FIG. 9 illustrates a stylized block diagram depiction of a semiconductor device comprising tunable timing circuits, in accordance with embodiments herein

FIG. 10 illustrates a flowchart depiction of a process for providing forward and/or reverse biasing for FD SOI devices, in accordance with embodiments herein; and

FIG. 11 illustrates a stylized depiction of a system for fabricating a semiconductor substrate on which FD SOI PMOS and NMOS devices may be formed, in accordance with some embodiments herein.

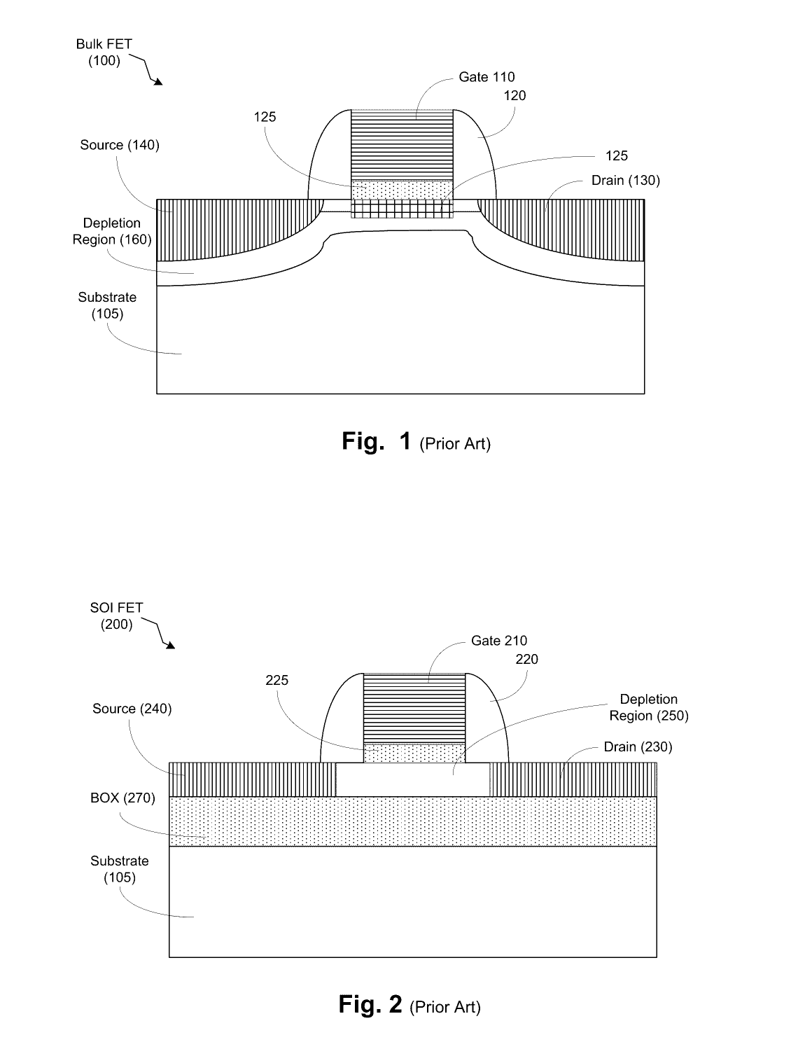

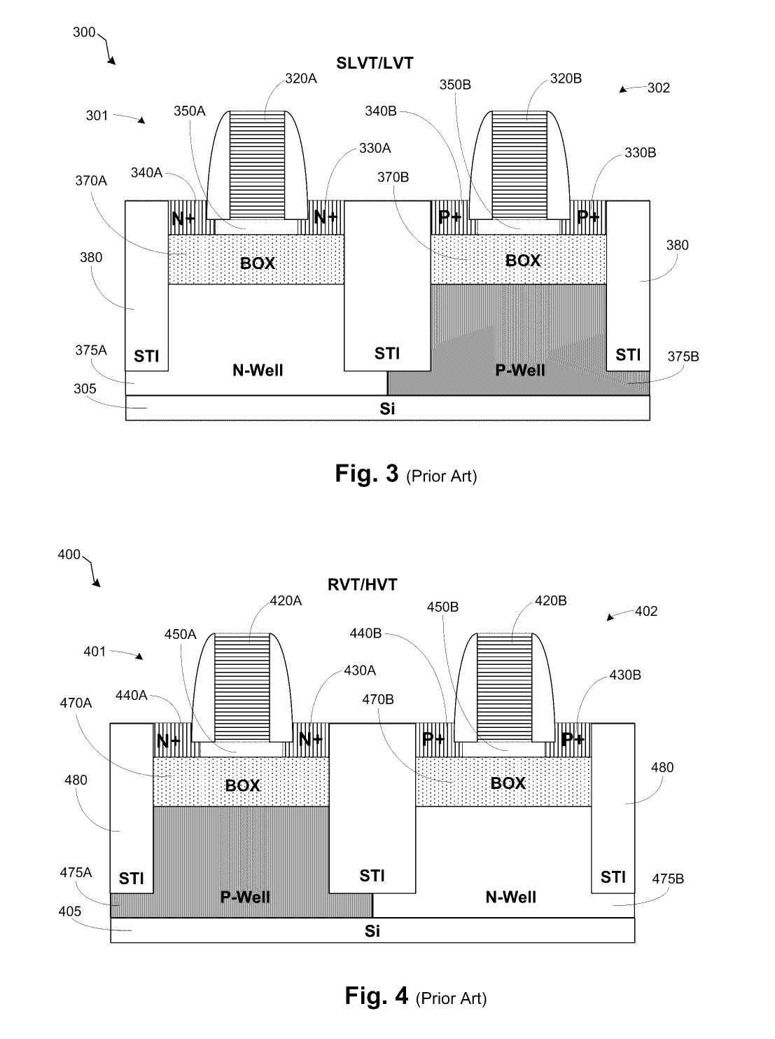

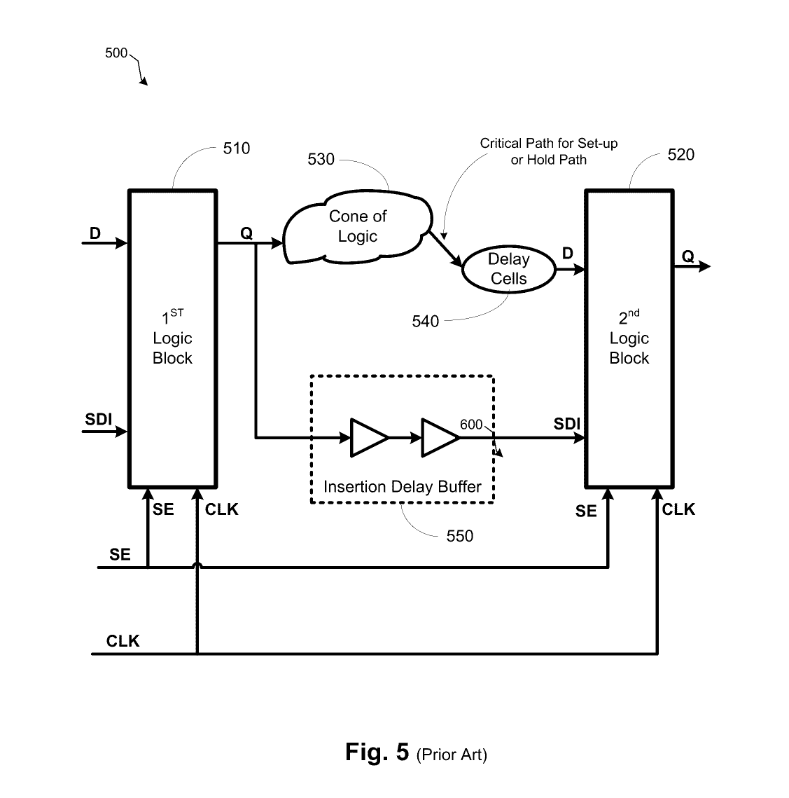

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for fabricating semiconductor substrate wafers for forming NMOS and/or PMOS devices, such as FD SOI transistors, e.g., 22FDSOI transistors. Embodiments herein provide for selectively applying forward and/or reverse biasing voltages to predetermined areas of a semiconductor device. The selectivity of applying the forward and/or reverse biasing voltages may comprise increasing the granularity of the selectivity above granularity of transistor-block level targeting. Further, embodiments herein provide for applying a tunable delay circuit for applying the biasing voltages in proper timing to reduce timing errors.

Embodiments herein provide for determining the locations of a semiconductor device for which forward and/or reverse biasing voltage signals are to be applied. Such locations may be targeted by routing predetermined voltage signals to provide such forward and/or reverse biasing voltage signals. Further, embodiments herein provide for implementing a tunable delay circuit to adjust the timing of the application of the forward and/or reverse biasing voltage signals. Application of embodiments herein may be applied to circuits comprising a variety of types of transistors, including FD SOI transistors, e.g., 22FDSOI transistors.

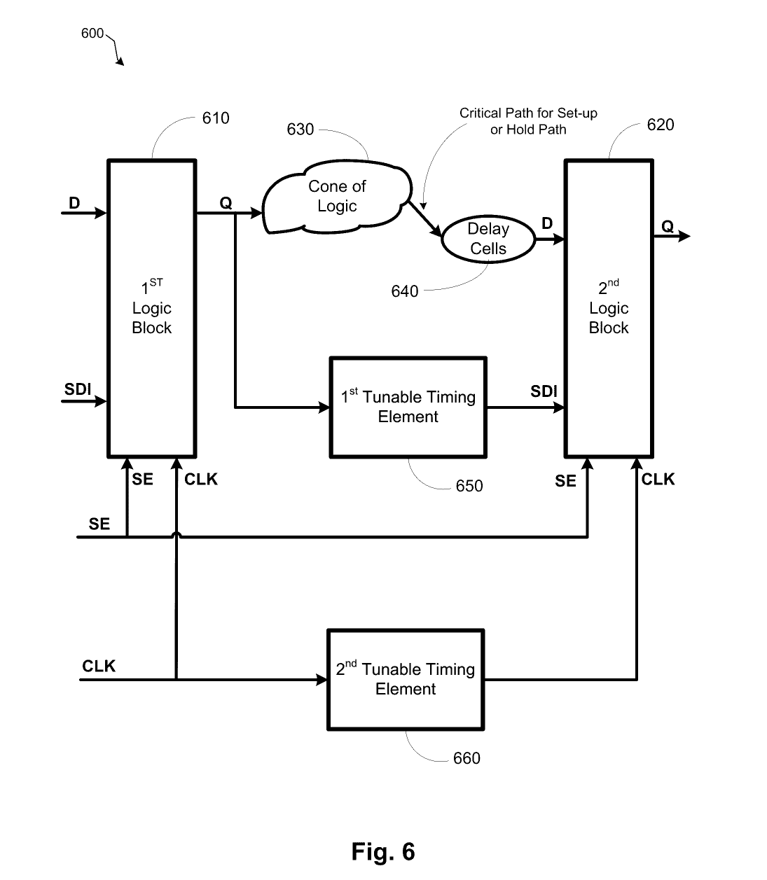

Turning now to FIG. 6, a stylized depiction of an exemplary circuit having FD SOI devices, in accordance with embodiment herein, is illustrated. A circuit 600 comprises a 1^{st} logic block 610, a 2^{nd} logic block 620, a cone of logic 630, a set of delay cells 640, and insertions delay buffers 650. The 1^{st} and 2^{nd} logic blocks 610, 620 may represent one or more registers and/or other logic.

The implementation of FD SOI FETs allows for lower operation voltages for the circuit 600, thus the V_{dd} minus V_{T} headroom is reduced. Embodiments herein provide for reducing the problems associated with lower headroom and lower operating voltages, such as such as timing failures, skew in the p/n ratio, V_{T} skew, RC coupling problems.

The path between the 1^{st} logic 620, the cone of logic 630, and the 2^{nd} logic block 620 may comprise critical areas with respect to SET-UP or HOLD paths. Delay cells 640 may be implemented to adjust of timing issues in this critical path. In some embodiments, in the design phase, tunable timing elements may be introduced. In one embodiment, a 1^{st} tunable timing element 650 may be implemented in the data path between the 1^{st} logic block 610 and the 2^{nd} logic block 620. Further, in some embodiments, a 2^{nd} tunable timing element may also be implemented to the clock path between the between the 1^{st} logic block 610 and the 2^{nd} logic block 620.

The 1^{st} and 2^{nd} tunable timing elements 650, 660 may comprise one or more clock elements and/or other circuitry capable of increasing the speed of predetermined paths by implementing forward biasing for FD SOI FETs that can be forward biased (e.g., LVT/SLVT FETs). Additionally, or alternatively, the 1^{st} and 2^{nd} tunable timing elements 650, 660 may comprise one or more clock elements and/or other circuitry capable of decreasing the speed of predetermined paths by implementing reverse biasing for FD SOI FETs that can be reversed biased (e.g., RVT/HVT FETs).

In alternative embodiments, tunable timing elements (e.g., the 1^{st} and 2^{nd} tunable timing elements 650, 660) may be implemented at predetermined locations on a semiconductor device to adjust for process, voltage, and/or temperature (PVT) variations. Forward or reverse biasing may be implemented by tunable timing elements (e.g., the 1^{st} and 2^{nd} tunable timing elements 650, 660).

The tunable timing elements provided by embodiments herein e.g., the 1^{st} and 2^{nd} tunable timing elements 650, 660) may be configured to have biasing capabilities. For example, the tunable timing elements 650, 660 may be configured to forward bias LVT/SLVT FETs and/or reverse bias RVT/HVT FETs. That is, tunable timing elements (e.g., the 1^{st} and 2^{nd} tunable timing elements 650, 660) may be capable of being adjusted such that faster or slower buffering functions may be provided.

In one embodiment, the tunable timing elements may comprise one or more clock trees with tunable buffers. The tunable timing elements are capable of selectively adjusting clock skew in clock branches. The tunable timing elements are capable speeding up or slowing down clock paths, which may reduce timing violations and/or improve performance. In one embodiment, the tunable timing elements may comprise one or more phase-locked loop (PLL) circuitry to lock adjusted clock signals with the primary phase of the clock tree.

In one embodiment, granular biasing supply voltage signals may be provided in parallel to a clock network that is used to operate the circuit 600. In an alternative embodiment, existing power supply on a semiconductor device may be used. In yet another embodiment, transistors may be used to generate the voltage supplies from the primary voltage signal from a main power supply. In one embodiment, the size of the transistors formed would be relatively small in response to the biasing voltage being small. Generally, this would be the case for adjusting a small amount of timing skew. In this embodiment, the power leakage would also be relatively small since the biasing voltage is applied to the well. These voltage signals may be used to perform appropriate forward biasing and/or reverse biasing at predetermined critical paths in circuits of a semiconductor device.

In one embodiment, the tunable timing elements may comprise, or may be operatively coupled to, a non-volatile memory that is capable of storing biasing information, which may be used to perform dynamic performance adjustments on semiconductor devices in the field. The performance adjust may include, but are not limited to increasing Fmax, reducing dynamic power, etc. The forward and reverse biasing performed by the tunable timing elements may be designed to adjust both the threshold voltage and p/n ratio in order to reduce timing violation and improve data paths. Further, these biasing and timing adjustments may be made to improve performance of a semiconductor device.

Those skilled in the art having benefit of the present disclosure would appreciate that the circuit illustrated in FIG. 6 is provided as an example for implementing embodiments herein. Embodiments herein may be implemented in a variety of circuits and remain within the spirit and scope of embodiments and claims herein.

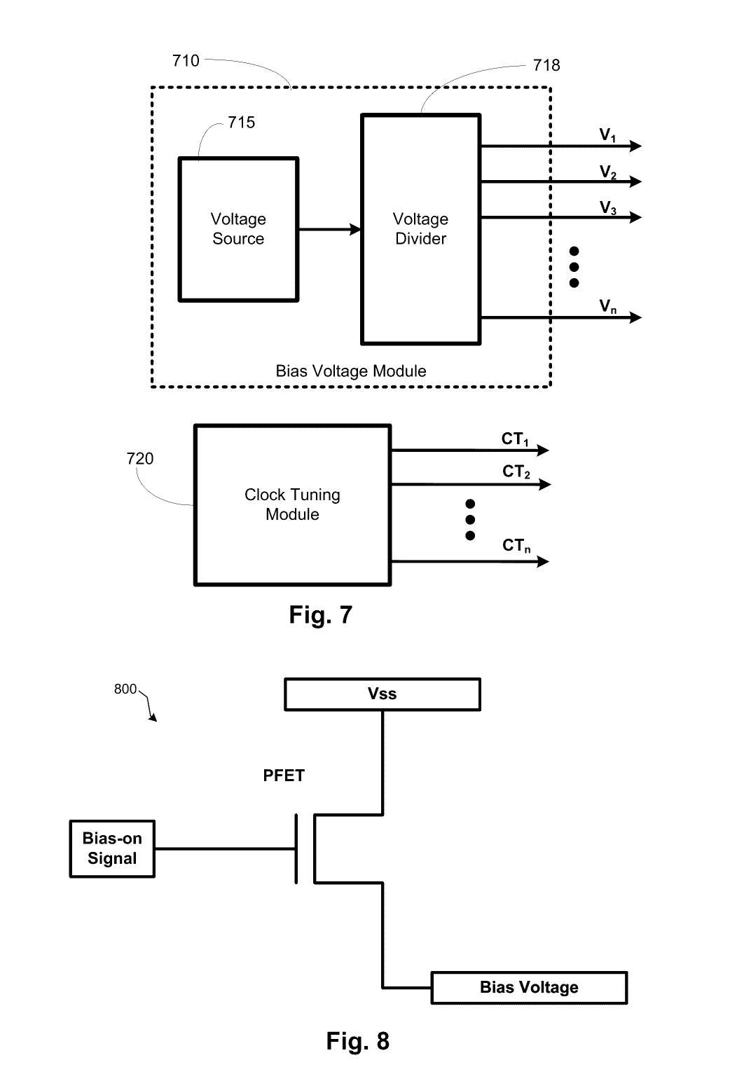

Turning now to FIG. 7, a stylized block diagram depiction of a bias voltage module and a clock tuning module, in accordance with embodiments herein, is illustrated. In one embodiment, the bias voltage module 710 and/or the clock tuning module 720 may be part of the tunable timing elements of FIG. 6. In an alternative embodiment, the bias voltage module 710 and/or the clock tuning module 720 may be separate, standalone circuit that provides timing signals and/or bias voltage signals to tunable timing circuits, such as the tunable timing elements of FIG. 6.

The bias voltage source comprises a voltage source 715 and a voltage divider 718. The voltage source 715 may comprise a charge pump circuit or other energy sources configured to provide a predetermined voltage signal. In some embodiments, the voltage source 715 may comprise a voltage regulator or other regulation circuit(s) known to those skilled in the art.

A voltage signal from the voltage source 715 may be provided to the voltage divider 718. The voltage divider 718 may comprise one or more divider circuits configured using various types of resistors, FETs, etc. The voltage divider 718 may generate a plurality of predetermined divided voltage signals (V₁, V₂, V₃, . . . Vₙ) of similar or different values. The predetermined values of the divided voltage signals may be designed to provide forward bias voltages and/or reverse bias voltages. The divided voltage signals may be signals of various predetermined voltage levels that may be used by the tunable timing elements described above for performing reverse and/or forward biasing functions.

In one embodiment, the bias voltage module 710 may comprise a PFET circuit to generate a bias voltage, as exemplified in FIG. 8. A PFET circuit 800 comprises a PFET device that is tied to Vdd. The PFET device may receive a bias-on signal at its gate. The bias-on signal, when asserted, turns on the PFET and provides a bias voltage signal, as shown in FIG. 8.

Turning back to FIG. 7, the clock tuning module 720 may generate various clock tuning control signals (CT₁, CT₂, CT₃, . . . CTₙ). The clock tuning module 720 may comprise various circuitry that may be used to generate the timing control signals (CT₁, CT₂, CT₃, . . . CTₙ). In one example, the bias-on signal of FIG. 8 may be controlled by one of the timing control signals. In another embodiment, the timing control signals may be used to control circuitry that affects the speed of signals lines on which the tunable timing elements are positioned.

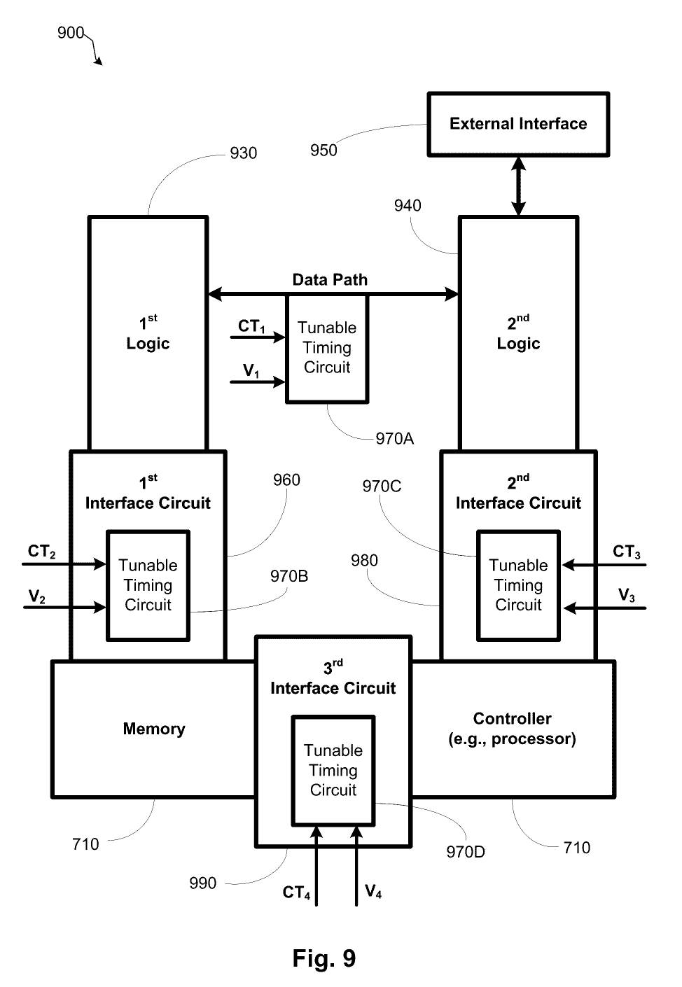

Turning now to FIG. 9, a stylized block diagram depiction of a semiconductor device 900 comprising tunable timing circuits, in accordance with embodiments herein, is illustrated. In one embodiment, the device 900 may comprise controller 910 (e.g., a processor), a memory 920, a 1^{st} logic circuit 930, a 2^{nd} logic circuit 950, and an external interface 950. In one embodiment, the device 900 may be a single semiconductor chip. In other embodiments, the device 900 may be a printed circuit (PC) board. In yet other embodiments, the device 900 may be a standalone device. Those skilled in the art would appreciate that the device 900 may comprise other circuit portions, such as voltage supply, etc.

The external interface 950 allows for communications between the device 900 and external devices. In one embodiment, the 2^{nd} logic 940 directs such communications. Additionally, the device 900 may comprise various interface circuits between the logic blocks 930, 940, memory 920, and the controller 910. For example, in the data path between the 1^{st} and 2^{nd} logic blocks 930, 940 may comprise a tunable timing circuit 970A. A determination may be made that adjustments to the timing of the circuitry associated with the data path may be required. As such, a bias voltage signal, V₁, and a timing control signal CT₁, may be provided to the tunable timing circuit 970A. In this manner a targeted forward and/or reverse biasing of specific FD SOI transistor or set of transistors may be performed.

A 1^{st} interface circuit 960 may provide for communications between the memory 920 and the 1^{st} logic 930. A determination may be made that adjustments to the timing of the 1^{st} interface circuit 960 may be required. In one embodiment, during the design process, a tunable timing circuit 970B may be designed into the 1^{st} interface circuit 960. A bias voltage signal, V₂, and a timing control signal CT₂, may be provided to the tunable timing circuit 970B. Thus, a targeted forward and/or reverse biasing of a specific FD SOI transistor or a set of transistors in the 1st interface circuit 960 may be performed.

A 2^{nd} interface circuit 980 may provide communications between the controller 940 and the 2^{nd} logic 930. A determination may be made that adjustments to the timing of the 2^{nd} interface circuit 980 may be required. In one embodiment, during the design process, a tunable timing circuit 970C may be designed into the 2^{nd} interface circuit 980. A bias voltage signal, V₃, and a timing control signal, CT₃, may be provided to the tunable timing circuit 970C. Thus, a targeted forward and/or reverse biasing of specific FD SOI transistor or set of transistors in the 2^{nd} interface circuit 980 may be performed.

Similarly a 3^{rd} interface circuit 990 may provide communications between the controller 940 and the memory 920. A determination may be made that adjustments to the timing of the 3^{rd} interface circuit 990 may be required. In one embodiment, during the design process, a tunable timing circuit 970D may be designed into the 3^{rd} interface circuit 990. A bias voltage signal, V₄, and a timing control signal, CT₄, may be provided to the tunable timing circuit 970D. Thus, a targeted forward and/or reverse biasing of specific FD SOI transistor or set of transistors in the 3^{rd} interface circuit 990 may be performed. As described above, the tunable timing circuits 970A-D that are implemented in the device 990 may provide for timing corrections as well as performance enhancements using forward and/or reverse biasing.

The tunable timing circuit 970A-D may be used to adjust the operation speed of the various circuits described above. These adjustments may be made to reduce timing violations, increase performance, and/or compensate for PVT issues.

Those skilled in the art having benefit of the present disclosure would appreciate that the circuit illustrated in FIG. 7 is provided as an example for implementing embodiments herein. Embodiments herein may be implemented in a variety of circuits and remain within the spirit and scope of embodiments and claims herein.

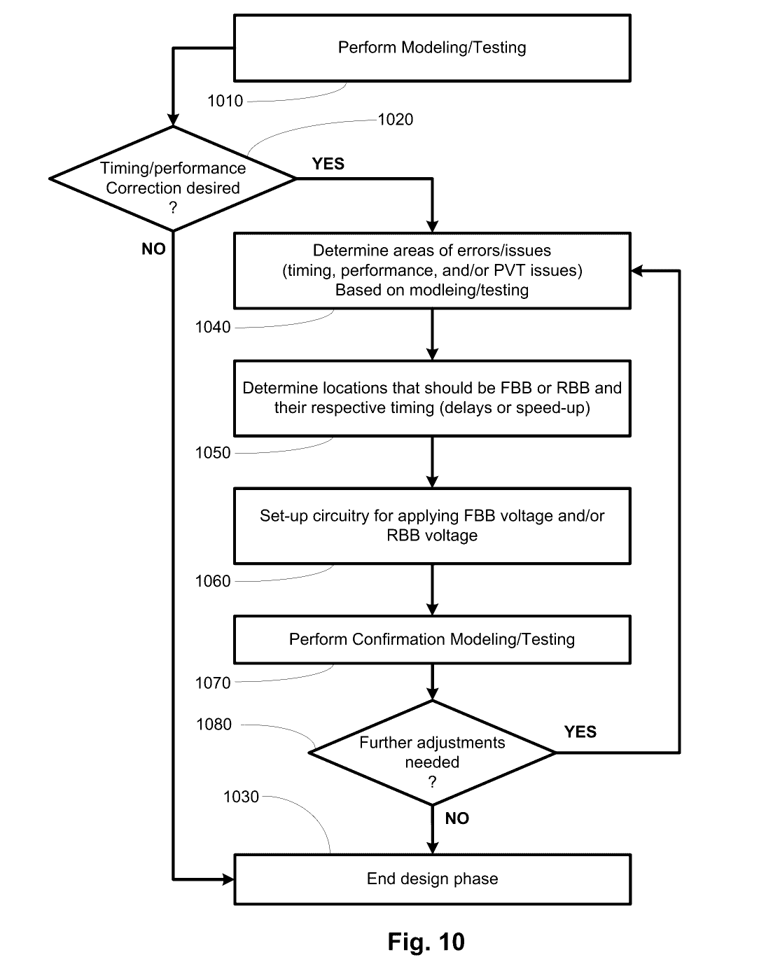

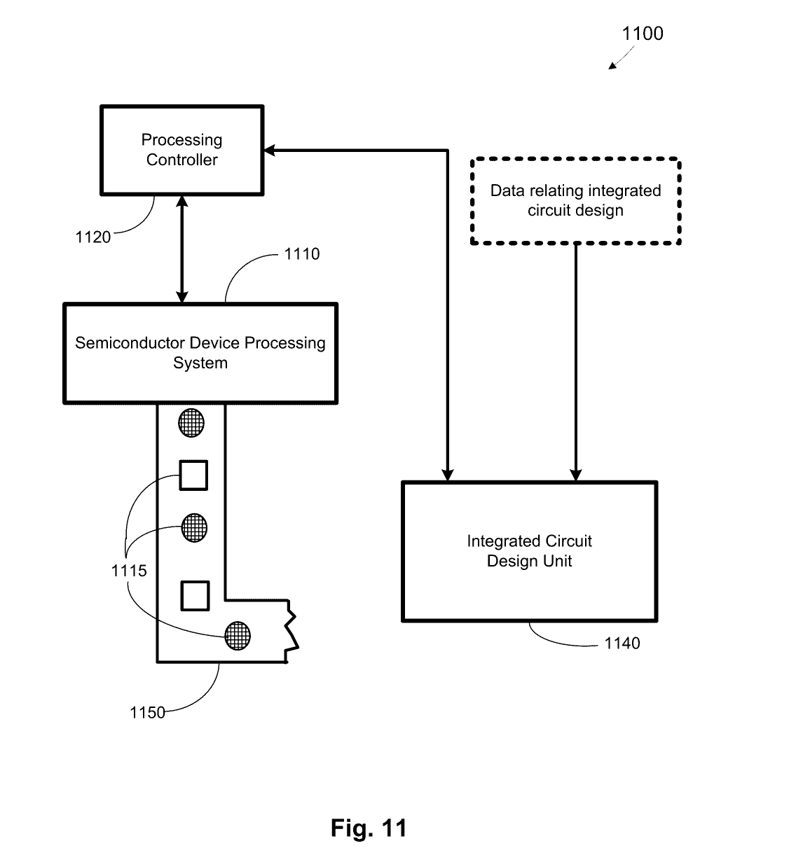

Turning now to FIG. 10, a flowchart depiction of a process for providing forward and/or reverse biasing for FD SOI devices, in accordance with embodiments herein is provided. In one embodiment, based upon an initial design of a semiconductor device comprising FD SOI devices, a modeling and/or testing of that design is performed (at block 1010). A determination is made whether timing or performance corrections are desired based upon the modeling/testing function (at block 1020). In the event that timing or performance corrections are not desired, the design phase may be terminated (block 1030).

However, if a determination is made that timing or performance corrections are desired, one or more areas of potential error (e.g., timing failures, performance below predetermined threshold levels, PVT issues, etc.) may be determined (at block 1040). This determination may be made by analyzing the modeling/testing data, performing further modeling/testing, and/or selecting circuit areas that are known to have timing or performance issues, such as interface regions between two major circuit components (e.g., interface regions between processor and memory). In one embodiment, this determination may include determining a circuit area in which an operation speed is be increased or decreased, or determining a circuit area in which a functionality can be restored to at least one of a pre-silicon tuning or a post-silicon tuning at a wider operating condition.

Based upon determining circuit areas that may have timing, performance issues, and/or PVT issues, a determination may be made as to areas that should be forward biased and/or areas that should be reversed biased (at block 1050). This includes identifying a particular transistor or sets of transistors that are LVT/SLVT configured for forward biasing and/or identifying a particular transistor or sets of transistors that are RVT/HVT configured for reverse biasing.

Upon determining the areas of potential timing, performance, and/or PVT issues, as well as the transistors that require forward or reverse biasing, a circuitry and wiring may be designed into the semiconductor device for delivering the required voltages for forward and/or reverse biasing and timing correction (at block 1060). This includes designing in various tunable timing circuits, as described above. Further, the various divided voltages and/or the timing control signals described above may be designed and wired to the tunable timing circuits. In this manner, certain interface regions or data paths may be sped up or slowed down in order to adjust for timing, performance, and/or PVT issues. The steps described in blocks 1040-1160 may be considered to be an optimizing function for optimizing the performance of the semiconductor device under design.

Upon designing in the tunable circuitry described in the context of block 1060, in one embodiment, a further confirmation modeling/testing process may be performed (at block 1070). This modeling/testing process may be more limited to modeling and/or testing specific areas that have been altered in the context of blocks 1040-1160. A determination is made whether further adjustments to the timing or performance of the semiconductor device is required as a result of the confirmation modeling/testing (at block 1080). If a determination is made that further adjustments are required, the optimizing functions (blocks 1040-1160) may be repeated. If a determination that further adjustments are not required, the design phase may be terminated (at block 1030). The steps described in FIG. 10 may be performed automatically by a process control system, similar to the system described below in FIG. 11.

Turning now to FIG. 11, a stylized depiction of the semiconductor device system capable of designing and manufacturing semiconductor devices in accordance with embodiments herein, is illustrated. The semiconductor device processing system 1110 may comprise various processing stations, such as etch process stations, photolithography process stations, CMP process stations, etc. One or more of the processing steps performed by the processing system 1110 may be controlled by the processing controller 1120. The processing controller 1120 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 1110 may produce integrated circuits on a medium, such as silicon wafers. The production of integrated circuits by the device processing system 1110 may be based upon the circuit designs provided by the integrated circuits design unit 1140. The processing system 1110 may provide processed integrated circuits/devices 1115 on a transport mechanism 1150, such as a conveyor system. In some embodiments, the conveyor system may be sophisticated clean room transport systems that are capable of transporting semiconductor wafers. In one embodiment, the semiconductor device processing system 1110 may comprise a plurality of processing steps, e.g., the 1^{st} process step, the 2^{nd} process set, etc., as described above.

In some embodiments, the items labeled “1115” may represent individual wafers, and in other embodiments, the items 1115 may represent a group of semiconductor wafers, e.g., a “lot” of semiconductor wafers. The integrated circuit or device 1115 may be a transistor, a capacitor, a resistor, a memory cell, a processor, and/or the like. In one embodiment, the device 1115 is a transistor and the dielectric layer is a gate insulation layer for the transistor.

The integrated circuit design unit 1140 of the system 1100 is capable of providing a circuit design that may be manufactured by the semiconductor processing system 1110. The design unit 1140 may receive data relating to the design specifications for the integrated circuits to be designed. In one embodiment, the integrated circuit design unit 1140 may perform a modeling of a device design and/or testing of processed semiconductor devices to determine whether certain regions of the design or device should be provided with forward or reverse biasing and timing adjustments, as described above. The integrated circuit design unit 1140 is capable of analyzing and performing design adjustments to provide, route, and implement forward and/or reverse biasing voltages. The design adjustments described in FIG. 10 may be automatically performed by the system 1100.

In other embodiments, the integrated circuit design unit 1140 may perform an automated determination of area that require design adjustments to provide, route, and implement forward and/or reverse biasing voltages and timing adjustments, and automatically incorporate design adjustments into the device design. For example, once a designer or a user of the integrated circuit design unit 1140 generates a design using a graphical user interface to communicate with the integrated circuit design unit 1140, the unit 1140 may perform automated modification of the design.

The system 1100 may be capable of performing analysis and manufacturing of various products involving various technologies. For example, the system 1100 may design and production data for manufacturing devices of CMOS technology, Flash technology, BiCMOS technology, power devices, controllers, processors, memory devices (e.g., DRAM devices), NAND memory devices, and/or various other semiconductor technologies.

Although in some examples, circuits herein were described in terms of FD SOI devices for consistency and ease of illustration, those skilled in the art would appreciate that concepts described herein may also apply to other SOI devices (e.g., partially depleted (PD) SOI devices) and remain within the scope of embodiments herein. The concepts and embodiments described herein may apply to a plurality of types of VT families of devices, including but limited to, FD SOI LVT transistors, FD SOI SLVT transistors, FD SOI RVT transistor, FD SOI HVT transistors, or combination herein, and remain within the scope of the embodiments herein. The concepts and embodiments herein may be applied to any VT family of transistors in the technology described above (e.g., if ULVt or UHVt is generated).

The system 1100 may be capable of manufacturing and testing various products that include transistors with active and inactive gates involving various technologies. For example, the system 1100 may provide for manufacturing and testing products relating to CMOS technology, flash technology, BiCMOS technology, power devices, memory devices (e.g., DRAM devices), NAND memory devices, processors, and/or various other semiconductor technologies.

The methods described above may be governed by instructions that are stored in a non-transitory computer readable storage medium and that are executed by, e.g., a processor in a computing device. Each of the operations described herein (e.g., FIGS. 10 and 11) may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method, comprising:
performing an operation modeling of a semiconductor device circuit design;
identifying at least one transistor for providing at least one of a first voltage for forward biasing said transistor or a second voltage for reverse biasing said transistor; and
providing, selectively, a delay for adjusting a timing associated with said transistor based upon identifying said at least one transistor.

2. The method of claim 1, wherein performing said operation modeling of said semiconductor device circuit design comprises at least one of testing for timing errors, determining a design change for reducing timing errors, or determining a design change for improving a performance of said semiconductor device circuit design.

3. The method of claim 1, wherein identifying at least one transistor comprises identifying at least one of an FD SOI LVT transistor, an FD SOI SLVT transistor, an FD SOI RVT transistor, an FD SOI HVT transistor, or a combination thereof.

4. The method of claim 1, wherein identifying at least one transistor comprises determining at least one of:
a circuit area in which an operation speed is be increased or decreased
a circuit area in which a functionality can be restored to at least one of a pre-silicon tuning or a post-silicon tuning at a wider operating condition.

5. The method of claim 4, further comprising providing a forward bias voltage in response to determining that said operation speed is to be increased and providing a reverse bias voltage to said circuit area is to be decreased.

6. The method of claim 4, further comprising providing a tunable delay circuit for said circuit area, wherein said tunable delay circuit can be configured to adjust the operation speed or functionality of said circuit area for at least one of reducing a timing error, improving performance of said circuit design, or compensating for process, voltage, and/or temperature (PVT) variations.

7. The method of claim 5, further comprising providing at least a one of a forward bias voltage signal or a reverse bias voltage signal for controlling the operation of said tunable delay circuit.

8. The method of claim 1, wherein identifying at least one transistor comprises identifying an interface region between a first circuit component and a second circuit component.

9. The method of claim 1, further comprising performing a processing of a semiconductor wafer to form a plurality of semiconductor devices based upon said semiconductor device circuit design comprising said delay.

10. A semiconductor device, comprising:
a first logic circuit;
a second logic circuit;
first interface circuit for operatively coupling said first logic circuit with said second logic circuit, said first interface circuit comprising at least one FD SOI transistor; and
a first tunable delay circuit operatively coupled to said interface circuit, said tunable delay circuit configured for adjusting an operation timing of said at least one FD SOI transistor.

11. The semiconductor device of claim 10, wherein said FD SOI transistor is at least one of an FD SOI LVT transistor, an FD SOI SLVT transistor, an FD SOI RVT transistor, or an FD SOI HVT transistor

12. The semiconductor device of claim 10, further comprising at least one of:
a first wire for providing a forward bias voltage signal; and
a second wire for providing a reverse bias voltage signal.

13. The semiconductor device of claim 12, wherein said at least one of said first wire or said second wire being routed to said first tunable delay circuit for adjusting said operation timing of said at least FD SOI transistor.

14. The semiconductor device of claim 10, further comprising a processor;
a memory device;
a second interface circuit for operatively coupled said processor and said memory device, said second interface circuit comprising a plurality of FD SOI transistors; and
a second tunable delay circuit operatively coupled to said interface circuit, said tunable delay circuit configured for adjusting an operation timing of said FD SOI transistors.

15. The semiconductor device of claim 14, further comprising:
a voltage source for providing at least one of a forward bias voltage and a reverse bias voltage, wherein said forward bias voltage and said reverse bias voltage are routed to said second tunable delay circuit for adjusting said operation timing of said FD SOI transistors.

16. A system, comprising:
a semiconductor device processing system to process a semiconductor wafer for manufacturing a semiconductor device based upon a device design, said semiconductor device processing system comprising:
a design unit configured to:
perform an operation modeling of said device design;
identify at least one circuit portion of said semiconductor device for providing at least one of a first voltage for forward biasing said transistor or a second voltage for reverse biasing said transistor; and
provide, selectively, a tunable delay for adjusting a timing associated with said transistor based upon identifying said at least one transistor for providing said at least one of a first voltage for forward biasing said transistor or a second voltage for reverse biasing said transistor for generating a final version of said device design;
and
a processing controller operatively coupled to said semiconductor device processing system, said processing controller configured to control an operation of said semiconductor device processing system for manufacturing said semiconductor device based upon said final version of said device design.

17. The system of claim 16, wherein said design unit is further configured to identify at least one of an FD SOI LVT transistor, an FD SOI SLVT transistor, an FD SOI RVT transistor, or an FD SOI HVT transistor.

18. The system of claim 16, wherein said design unit being configured to identify said circuit portion comprises at least one of:
identifying an interface between a first logic portion and a second logic portion;
identifying an interface between said first logic portion and a memory;
identifying an interface between said memory and a processor; and
identifying an interface between said processor and said second logic portion.

19. The system of claim 16, wherein said design unit being configured to identify at least one circuit portion of said semiconductor device for providing at least one of a first voltage for forward biasing said transistor or a second voltage for reverse biasing said transistor comprises determining whether said operation speed is to be increased and or decreased.

20. The system of claim 16, wherein said design unit being further configured to provide a tunable delay circuit for said circuit area, wherein said tunable delay circuit is capable of adjusting the operation speed of said circuit portion.
